(19) United States
(12) Patent Application Publication
(10) Pub. No.: US 2023/0411884 A1
(43) Pub. Date: Dec. 21, 2023

(54) AN IMPROVED CONNECTOR FOR A LOW INTERMODULATION BOARD-TO-BOARD OR BOARD TO FILTER RF COAXIAL CONNECTION ASSEMBLY, INTEGRATING AN ELASTIC BALL JOINT LINK

(71) Applicant: RADIALL, AUBERVILLIERS (FR)

(72) Inventors: Claude BROCHETON, Coublevie (FR); Senmiao HU, Shanghai (CN)

(21) Appl. No.: 18/253,217

(22) PCT Filed: Mar. 30, 2021
(86) PCT No.: PCT/CN2021/084138

§ 371 Date: May 17, 2023

(51) Int. Cl. H01R 12/91; H01R 24/50; H01R 12/70

(52) U.S. Cl. CPC H01R 12/91; H01R 24/50; H01R 12/7076; H01R 2103/00

(57) ABSTRACT

The present application relates to a coaxial connector, intended to transmit radio frequency RF signals, including: two electrical insulating solid bodies coaxially interposed between the central contact and the outer contact of the connector, one of the two bodies being mechanically retained in one of the two rigid portions of the outer contact and mechanically retaining one of the two rigid portions of the central contact, whereas the other of the two bodies is mechanically retained in the other of the two rigid portions of the outer contact and mechanically retains the other of the two rigid portions of the central contact,
wherein the ends of the two insulating bodies which are face-to-face and the flexible portions are configured to allow a ball joint link in flexion around an axis (Z) perpendicular to the longitudinal axes (X1, X2).

### TECHNICAL FIELD

The present invention relates to the field of electrical connexion and more particularly relates to a unitary RF connector.

Such a unitary connector can be used in particular to link two parallel printed circuit boards, usually called a board-to-board (B2B) connection or even a printed circuit board (PCB) to another component such as a module or a filter, usually called board to filter or board to module.

The applications particularly targeted by the invention are the connection of telecommunication equipment such as base transceiver stations BTS, RRU/RRH (Remote Radio Unit/Remote Radio Head) units, antenna integrated RRU/RRH solution, Telecom Massive MIMO antenna applications, and distributed antenna systems for the wireless communications market.

The invention also relates generally to the connectors in the telecommunication domain, in the medical domain, the industrial domain, the aeronautical domain, the transport domain and the space domain.

The connectors according to the invention can be used in particular to link two parallel printed circuit boards, usually called a board-to-board connecting system or even a printed circuit board to another component such as a module, a filter or a power amplifier or an antenna, or module to module.

By “RF connector”, it is to be understood a connector able to transmit signals from the Direct Current (DC) range to the radiofrequency (RF) range, including the hyperfrequency (HF) range, the signals being high speed digital signals (HSDL for High Speed Data Link) or radiofrequency (RF) signals.

By ‘unitary’ it is meant that the connector according to the invention, once assembled, forms a single object.

### PRIOR ART

With the continuous development of wireless communication technology, board to board connectors are becoming more and more widely used in wireless system module interconnection, such as communication base station, RRH, repeater, GPS devices, and other similar applications. Three major trends of wireless devices are smaller dimensions, lower cost, and easier installation. For a board to board connection, the market also requires them to be smaller, cheaper and more modularized.

There are already on the market and in the prior art examples of connection assemblies dedicated to the telecommunications sector for cellular radiotelephony intrabodies. In fact, the trend in this market is to minimize the losses of the RF (radiofrequency) part in order to reduce the amplifying components of the base stations. For this, on the one hand, the current radio part of the stations is being increasingly relocated as close as possible to the transmission-reception antennas, in the RRU/RRH transmitter modules, and on the other hand, the RF leads internal to the radio unit are being replaced by direct interconnections.

So-called board-to-board connections have thus been developed according to the successive generations of the last decade.

One main type of connection assemblies for interconnecting boards are represented by the SMP series for example. This type of assembly is described in the patent application WO 2010/010524 for example.

Such connection assemblies respectively consist of a first socket of snap-fitting (or “snap”) type, a second socket of “sliding” (or smooth bore) type with a guiding cone (“slide on receptacle”), and a connection coupling called adaptor, with the first and second sockets respectively fastened to the ends thereof.

The connection is therefore made blind by the re-centring of the connection coupling by means of a guiding cone of the sliding socket. The radial misalignment compensation is obtained by a rotation of the coupling in the groove of the snap-fitting socket. The first and second sockets are conventionally made of brass. The connection coupling is typically made of an expensive noble metallic material, for example CuBe2 or CuSn4Pb4Zn4, and provided at each of its ends with flexible means (petals and slots for example) that cooperate with the first and second sockets.

SMP series are standardized in accordance with MIL STD 348 specifications, the DESC specifications 94007 & 94008A second generation of connection assemblies is also known. Axial misalignment tolerances vary from 2 mm to 2.4 mm, for example marketed under the names SMP-MAX by the company Radiall or else marketed under the names MMBX by the company Huber and Suhner or else marketed under the name AFI by the company Amphenol RF, or else marketed under the name Long Wipe SIP and P-SMP by the company Rosenberger.

However, these board-to-board connections present a significant number of drawbacks.

On one hand, the radial misalignment is compensated by a rotational movement achieved by two components. The cost of manufacturing of these connection systems as well as the integration costs of the two components is relatively high, thus constituting a brake for this type of market.

Moreover, when unmated, the adapter does not systematically place itself into a vertical position. If this initial tilted position is not sufficient to prevent the end of the adapter to be introduced correctly into the guiding cone, during mating, the damages may be very important.

On the other hand, the configuration of the connections does not make it possible to obtain a sufficiently great radial and/or axial misalignment. Significant rotation angles, typically greater than 3, cannot be reached without causing an undesirable permanent deformation of the elastic means of the coupling. This permanent deformation causes a significant degradation of the electrical performance levels (electrical continuity), which de facto limits the radial misalignment allowed, in particular for a small distance between boards to be connected.

At last, the cost of producing these connections is relatively high, thus constituting a brake for this type of market. These connections also require three different components. Producing the connection coupling from a noble material, in particular when the coupling has a significant length, and producing possible slots in this coupling results in not-inconsiderable production costs. And the manufacturing processes include machining, the cost of which is also high.

In the case of the connection assembly according to the patent application WO 2010/010524, said connection needs in fact three different pieces which are connector components, namely two receptacles which are each soldered on a PCB and one elongated rigid coupling to connect together the two receptacles. When applied in massive board to board connection, it might result from this type of solution a very big insertion force and make the connection between two PCB difficult.

Another current solution to realize a board-to-board connection is described in U.S. Pat. No. 6,231,352B1 patent. The disclosed coaxial coupling allows to adopt only one unitary connector to realize the board-to-board connection.

In WO2017/054106 patent application, the applicants have also proposed a unitary RF connector with an electrically insulating block which serves as a rigid support for flexible conductive components whose central portions are rigidly respectively held therein and/or on the outer wall of the block. This solution is good for applications which require some modularization and standardization.

FR3086111A1 patent application proposed a microwave coaxial connector unit comprising at least one elastic return means by compression arranged outside of the ground contact which is adapted to generate restoring forces on the ground contacts sliding along an axis parallel to the axis of the connector, but not coincident with the latter, and which makes it possible to establish a mechanical pressure between the end of the ground contact and one of the two PCBs to be connected. This solution allows a board-to-board connection over a short distance in a wide range, typically between 3 and 20 mm.

In WO2020/181429 patent application, the applicants have also proposed a unitary RF connector comprising a plane central contact with flexible branches to apply a contact force to a male pin of a complementary connector, and an insulator which serves as a guide and a centring of the male pin and enables its swivelling/tilting which authorizes radial misalignment between the two complementary connectors.

The international application filed on Oct. 2, 2019 under number PCT/CN2019/109802, also in the name of one of the applicants, proposes a unitary connector with an electrically insulating block which serves as a rigid support for the compressive conductive components whose central parts therein are respectively held rigidly for the central contact and on the outer wall of the block for the ground contact and with a crown arrangement of the plurality of free ends of the ground contact.

More generally, it is necessary to further improve the board-to-board or board-to-module or board-to-filter connections, particularly with less production costs, with increased misalignment tolerances and with higher fiability.

The invention aims to address all or some of these needs.

### EXPLANATION OF THE INVENTION

The subject of the invention is thus a coaxial connector, intended to transmit radio frequency RF signals, of longitudinal axis X, comprising:
a central contact comprising two rigid portions each extending along a longitudinal axis and a flexible portion between the two rigid portions and,
an outer contact comprising two rigid portions and a flexible portion between the two rigid portions,
two electrical insulating solid bodies coaxially interposed between the central contact and the outer contact, one of the two bodies being mechanically retained in one of the two rigid portions of the outer contact and mechanically retaining one of the two rigid portions of the central contact, whereas the other of the two bodies is mechanically retained in the other of the two rigid portions of the outer contact and mechanically retains the other of the two rigid portions of the central contact,
wherein the ends of the two insulating bodies which are face-to-face and the flexible portions are configured to allow a ball joint link in flexion around an axis perpendicular to the longitudinal axes.

This flexion is induced when an out-of-center compressive force generated during a mating between two printed circuit boards (PCBs) or between a PCB and a filter is applied to one end of the connector.

In a preferred embodiment, the flexible portions of the central and outer contacts are configured to enable elastic return of the connector to its initial position in which the longitudinal axes are aligned. Thus, the flexible portions are designed to remain in the elastic deformation range under normal work conditions, i.e. during a mating between two printed circuit boards (PCBs) or between a PCB and a filter.

Thus, the invention essentially consists of a unitary connector comprising central and outer contacts and two insulating bodies, designed to produce an elastic ball joint integrated directly into the connector. This elastic ball joint enables the connector to work in flexion during a connection between two PCB or between a PCB and a filter and thus to compensate for radial misalignment.

The elasticity of the connection conferred by the flexible portions of the central and outer contacts advantageously allows, as soon as the connector is not mechanically stressed, an automatic return to self-alignment of all the components of the connector.

Compared to the connectors according to the prior art, which are intended to link two printed boards or a printed board with a filter, notably such as described in WO 2010/010524 patent application, the ball joint link is integrated in a unitary assembly.

Compared to the connectors according to the prior art, notably such as described in PCT/CN2019/109802 patent application, the use of a pin/socket central contact increases the reliability of the removable connection achieved by a connector according to the invention.

Moreover, according to the invention, the elasticity of the connection conferred by the flexible portions of the central and outer contacts allows advantageously, as soon as the connector is not mechanically stressed, a self-alignment of all the components of the connector, i.e. a an automatic and systematic return to an aligned position, before any mating or after any un-mating. In other words, the connector is preferably such configured that, under normal work conditions, the flexible portions of the outer and central remain within the elastic deformation range and therefore the connector returns to a position in which all its components are aligned, i.e. the longitudinal axes of the insulating bodies are aligned.

In a preferred variant, the flexible portion of the central contact and/or the outer contact is (are) in the form of a pleated or corrugated bellows.

To increase the flexibility, the bellows may comprise through slits arranged by creating material discontinuities within the corrugations or pleats of the bellows.

In an advantageous variant, the surfaces of the two electrical insulating bodies which are face-to-face are complementary shapes.

In another variant, the surfaces of the two electrical insulating bodies which are face-to-face are configured to block the ball joint link in a given maximum rotation angle around the axis perpendicular to the longitudinal axes.

According to a preferred embodiment, the two electrical insulating bodies are designed in order to adapt the characteristic impedance of the connector.

According to this embodiment, at least one of the two electrical insulating bodies may comprise a plurality of holes distributed on its periphery.

Also, the internal periphery of each of the rigid portions of the outer contact may comprise tabs cooperating by snap-fastening with windows formed in the external periphery of each insulating body.

Preferably, at least one end of the central contact and/or of the outer contact is(are) slotted defining contact petals.

According to an advantageous variant, each of the outer contact and the central contact is a dissymmetric body, the flexible portions being not centred to the middle of said outer and central contacts.

Preferably, the central contact and/or the outer contact are each a unique piece made by stamping from a metal sheet.

According to another embodiment, at least one end of the outer contact comprising a base, intended to serve as a permanent electrical and mechanical connection with a printed circuit board (PCB1).

The invention concerns also a coaxial connection assembly, intended in particular to link two printed circuit boards (PCBs) or a PCB and a module (F), comprises:
a coaxial connector such as described above, intended to be connected to a first printed circuit board,
a receptacle forming a end socket, called sliding end socket, intended to be integrated in a module or connected to a second printed circuit board,
wherein one end of said first connector is intended to slide in the receptacle.

### DETAILED DESCRIPTION

Other advantages and features of the invention will become more apparent on reading the detailed description of exemplary implementations of the invention, given as illustrative and non-limiting examples with reference to the following figures in which:

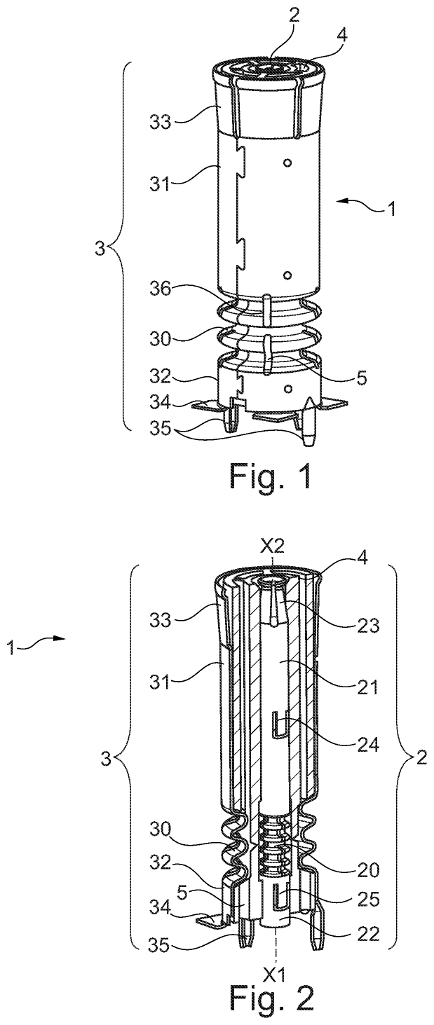

FIG. 1 is a perspective view of an example of a RF coaxial connector according to the invention;

FIG. 2 is a perspective view partly cut away of the exemplary coaxial connector according to FIG. 1;

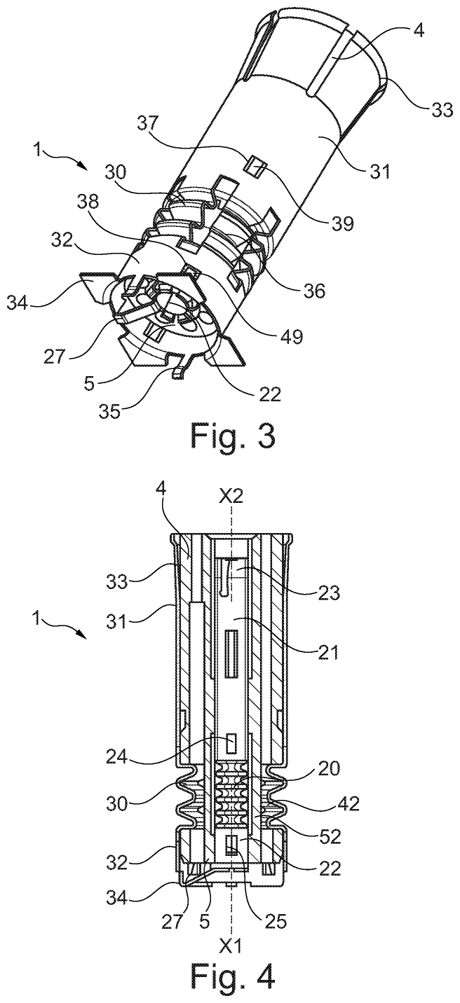

FIG. 3 is another perspective of the example of the connector according to FIG. 1;

FIG. 4 is a longitudinal cross-sectional view of the example of the connector according to FIG. 1;

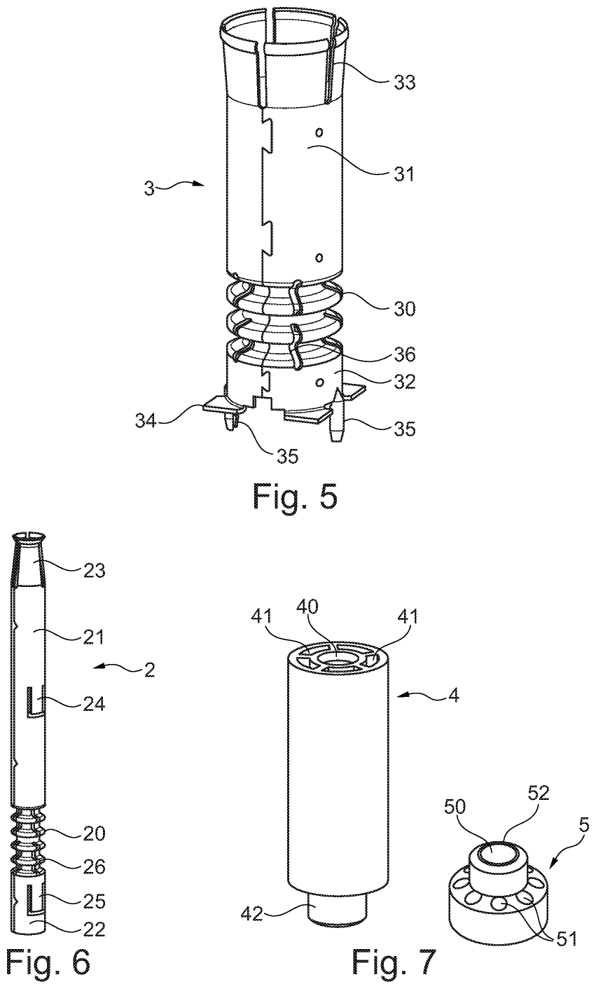

FIG. 5 is a perspective view of the outer contact of the connector of FIGS. 1 to 4;

FIG. 6 is a perspective view of the central contact of the connector of FIGS. 1 to 4;

FIG. 7 is a perspective view of the two electrical insulating bodies of the connector of FIGS. 1 to 4;

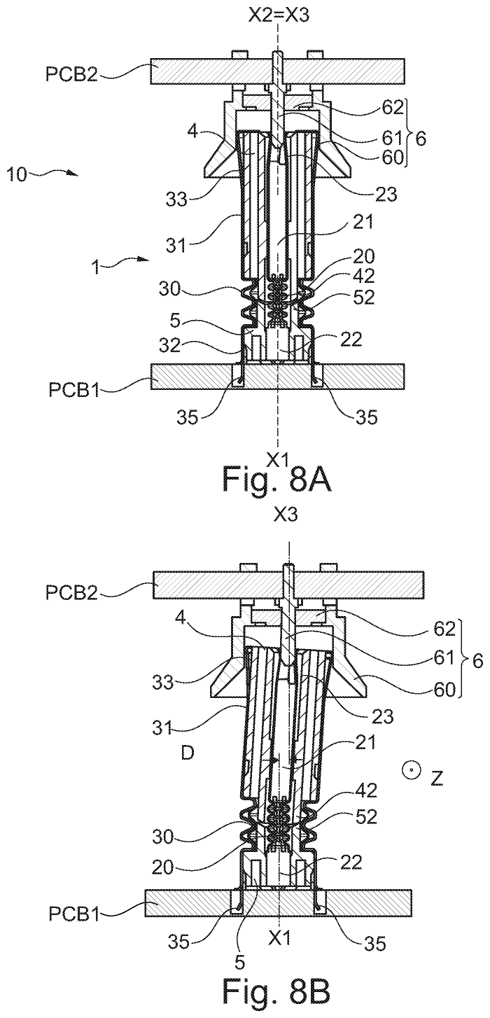

FIGS. 8A and 8B are longitudinal cross-sectional views of the connector of FIGS. 1 to 4, in a connection configuration with the sliding of the connector to link two printed circuit boards (PCB1, PCB2) respectively without and with radial misalignment;

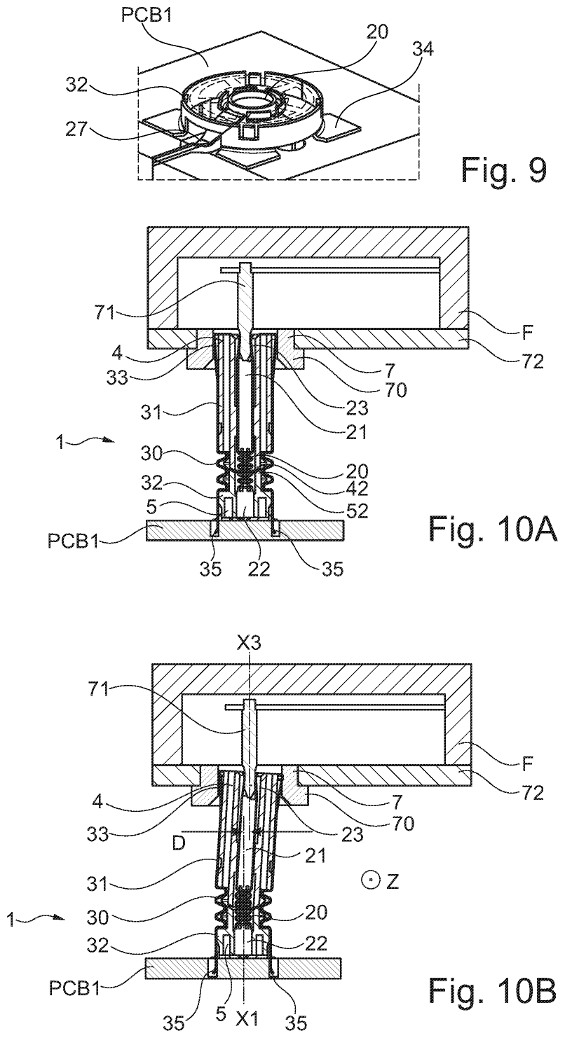

FIG. 9 is a perspective section view of the base of the connector according to FIGS. 1 to 4 showing the soldering to a printed circuit board (PCB1) with a tab extending radially to the longitudinal axis (X2) to link the central contact to a conductive track of the PCB1 with an angular indexing;

FIGS. 10A and 10B are longitudinal cross-sectional views of the connector of FIGS. 1 to 4, in a connection configuration with the sliding of the connector to link a printed circuit board (PCB1) and a filter (F) respectively without and with radial misalignment;

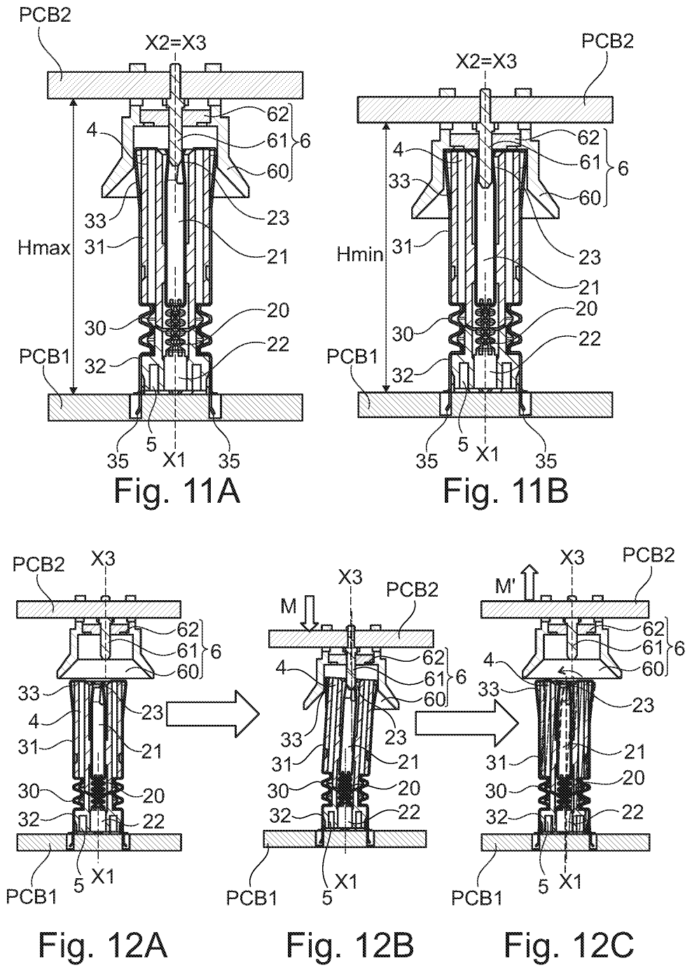

FIGS. 11A and 11B are longitudinal cross-sectional views of the exemplary RF coaxial connector according to FIGS. 1 to 4, showing different connection configurations with the sliding of the connector to respectively the maximum, and minimum board-to-module distance.

FIGS. 12A to 12C are longitudinal cross-sectional views of the exemplary RF coaxial connector according to FIGS. 1 to 4 showing respectively the steps of mating (connection) and unmating (disconnection) between two printed circuit boards (PCB1, PCB2).

For clarity purposes, the same references designating the same components of a connector according to the invention are used for all the FIGS. 1 to 12C.

In the framework of the invention, the terms “mating” and “connection” are the same notion, i.e. the link achieved by a RF coaxial connector according to the invention and “unmating” and “disconnection” designate the link not achieved.

Also, the term “vertical” means that the longitudinal axis X1 of the insulating body of the connector which is in permanent connection with a PCB (PCB1) is arranged vertically.

FIGS. 1 to 7 show a RF coaxial connector 1 and its different components.

The coaxial RF connector 1 is a unitary structure which comprises, as axisymmetric components, a central contact 2, an outer contact 3, also called ground contact and two electrical insulating solid bodies 4, 5 interposed coaxially between the central contact 2 and the outer contact 3.

Advantageously, each of the central contact 2 and the outer contact 3 are a unique piece made by stamping from a metal sheet.

The central contact 2 has the functions of RF signal transmission together with the ground contact 3 through the insulating bodies (including air), of conformance to dimensional characteristics requested by the equipment and of conformance to mechanical performances and assembling requests. Their general shapes are designed in order to adapt the impedance and transmit the RF signal with a minimum of losses and reflections.

The central contact 2 comprises two rigid portions 21, 22 each extending along a longitudinal axis X1, X2 and a flexible portion 20 between the two rigid portions 21, 22. In the illustrated example, the flexible portion 20 is in the form of a corrugated bellows. Also, in the illustrated example, one end of the central contact 2 is slotted defining contact petals 23.

The outer contact 3 comprises two rigid portions 31, 32 each extending along the longitudinal axis X1, X2 and a flexible portion 30 between the two rigid portions 31, 32. In the illustrated example, the flexible portion 30 is in the form of a corrugated bellows. Also, in the illustrated example, one end of the outer contact 3 is slotted defining contact petals 33.

In the illustrated example, the end opposed to the slotted end 33 is shaped as a base 34 to serve as a permanent connection with a printed circuit board PCB1.

This permanent connection can be achieved by welding and/or press fit and/or conductive gluing or any other traditional techniques of reporting components on PCBs.

Furthermore, in order to ensure the mechanical retention between the outer contact 3 of the connector 1 with the PCB1, the end of the outer contact 3 may comprise lugs 35 which extend parallel to longitudinal axis X1. These lugs may present a folding at their extremity in order to guarantee the mechanical retention during a second step soldering (double-sided PCB for example).

The insulating body 4 comprises a central housing 40 to house the rigid portion 21 and a part of the flexible portion 20 of the central contact 2. Around the central housing 40, a plurality of holes 41 are distributed at the periphery of the body 4. The end 42 of the body 4 may be spherical or frusto-conical.

The insulating body 4 is mechanically retained in the rigid portion 31 of the outer contact 3 and mechanically retains the rigid portion 21 of the central contact 2.

The insulating body 5 comprises a central housing 50 to house the rigid portion 22 and a part of the flexible portion 20 of the central contact 2. Around the central housing 50, a plurality of holes 51 are distributed at the periphery of the body 5. The end 52 of the body 5 may be spherical or frusto conical.

The holes 41 and 51 allow an impedance matching for the connector 1. In a general way, the ratio between the insulating air and the solid insulating material of the bodies 4 and 5 is designed to control the characteristic impedance of the complete connection line determined by the whole connector 1. Any other suitable means to adapt the impedance of the insulating bodies 4, 5 and so the impedance of the complete connection line determined by the whole connector 1 is also possible.

The insulating body 5 is mechanically retained in the rigid portion 32 of the outer contact 3 and mechanically retains the rigid portion 22 of the central contact 2.

The shape and the sizing of the insulating bodies 4, 5 allow them to support the rigid parts 21, 22 of the central contact 2, notably to prevent excessive deformation of it at any circumferential direction.

In the illustrated example, the mechanical retentions are achieved by snap-fitting. Thus, the external periphery of each of the rigid portions of the central contact 2 comprising tabs 24, 25 cooperating by snap-fastening with windows (not shown) formed in the interior periphery of each insulating body, 4, 5. In the same way, the internal periphery of each of the rigid portions of the outer contact 3 comprising tabs 39, 49 cooperating by snap-fastening with windows (not shown) formed in the external periphery of each insulating body, 4, 5. An alternative for mechanical retention is the use of punching holes shown in FIG. 5. Other types of retention can be foreseen.

According to the invention, the ends 42, 52 of the two insulating bodies 4, 5 which are face-to face, are preferably not in contact when the connector is not mated, i.e. when no mechanical constraint is applied to the connector 1. They are configured to allow a ball joint link between them. These surfaces may be of complementary shapes. The ends 42, 52 can be spherical or frusto-conical.

This ball joint link is elastic thanks to the flexible portions 20, 30 of the central 2 and outer 3 contacts in flexion around an axis Z perpendicular the longitudinal axes X1, X2, when a force generated by a mating between two printed circuit board PCB1, PCB2 or between a PCB and a filter, is applied to one end of the connector towards its interior without being applied along one of longitudinal axes X1, X2.

To adjust the bending moment of the elastic ball joint, the bellows of the central and outer contacts 2, 3 may comprise through slits 26, 36 arranged by creating material discontinuities within the corrugations.

Advantageously, the flexible portions 20, 30 are configured to remain under normal work conditions, in the elastic deformation range. Thus, they enable an elastic return of the connector to its initial position in which the longitudinal axes X1, X2 are aligned, when no mating force is applied to the connector.

FIGS. 8A and 8B show a coaxial connector assembly 10 between two printed circuit board PCB1, PCB2 the coaxial connection assembly 10 comprising a coaxial connector 1 such as described above and a receptacle 6 forming an end socket, called sliding end socket.

The base 34 of the outer contact 3 of the connector 1 is in permanent mechanical and electrical connection to PCB1 by brazing, welding or conductive gluing. The outer contact 3 is in electrical contact with conductive tracks of the PCB1. The central contact 2 is also in electrical contact with a conductive track of the PCB1 by the intermediate of a tab 27 extending radially to the longitudinal axis X1, which links said central contact to the conductive track of PCB1 with an angular indexing, as shown on FIG. 9. The receptacle 6 is brazed or welded to PCB2 and comprises a rigid body 60 with a recess, a contact pin 61 extending along a longitudinal axis X3, the recess of the body 60 being arranged at the periphery of the contact pin 61.

The rigid body 60 forms a ground outer contact.

An insulator 62 is positioned between the ground outer contact 60 and the contact pin 61.

The recess of the body 60 houses the contact pin 61 and the insulator 62.

The body 60 of the receptacle 6 is also a centring end piece comprising a centring surface which is of annular shape and of circular section, preferably frusto-conical.

FIG. 8A shows a mated state with no radial misalignment.

Now, the mating process will be described.

When the connector 1 is connected to the receptacle 6, as illustrated in FIG. 8A, the petals 23 of the end of the central contact 2 are open and in forced contact respectively with the contact pin 61.

On this slide side, the centring surface of the body 60 guides and ensures the connector 1 can be inserted into the receptacle 6 under blind mating.

FIG. 8B shows a mated state with radial misalignment.

During this mating, the rigid portions 21, 31 of the central and outer contacts 2, 3 rotate around the axis Z thanks to the ball joint link.

Thus, as shown on FIG. 8B, in the mated state, the flexible portions 20, 30 are in flexion and thus, the radial misalignment D between the longitudinal axes X1, X3 is compensated by the ball joint link of the connector 1.

As an indicative example, the flexion allowed by the elastic ball joint can be equal to +/−4° and the radial misalignment D can be equal to +/−1.2 mm.

The slotted end portions 23, 33 of respectively the central and outer contacts allow only an axial misalignment. As an indicative example, with a slotted portion 33 with five petals and a slotted portion 23 of the central contact with three petals, the axial misalignment can be equal to +/−1 mm. The slotted end portions 23, 33 also withstand the radial misalignement allowed by the ball joint link, thanks to the elastic deformation of the petals.

FIG. 9 shows the base 34 fixed to PCB1 with the conductive tab 27 in electrical contact with a conductive track of PCB1 with an angular indexing.

In FIGS. 10A and 10B, the PCB2 and its sliding receptacle 6 of the FIGS. 8A and 8B are replaced by a filter F and its integrated sliding receptacle 7, comprising a pin contact 71 and a filter body 70 retained in the filter lid 72.

Once the connector 1 is fixed to PCB1 by the intermediate of base 34, as described above, the sliding mating is achieved with the filter body 7 in the same way that previously with the receptacle 6 for a connection with PCB2.

FIGS. 11A and 11B show respectively the maximum height (Hmax) and the minimum height (Hmin) for a connection between PCB1 and PCB2 with a RF coaxial connector 1 according to the invention.

The axial tolerance between PCB1 and PCB2 is compensated by the sliding of the connector 1 into the end receptacle 6. While the axial height changed, the petals of the slotted portions 23, 33 of the central and outer contacts 2, 3 slide along the pin 61 and the internal surface of the ground contact 60 of the receptacle 6. The axial misalignment is compensated at the interface of the sliding receptacle only and not by the ball joint link. As an indicative example, the difference between maximum height and minimum height is of the order of 2 mm.

FIG. 12A shows an initial unmated state between PCB1 and PCB2 with the connector 1 fixed on PCB1.

FIG. 12B shows the next mated state after displacement of PCB2 according to the M direction.

FIG. 12C shows the final unmated state after unmating by displacing PCB2 according to the opposite M′ direction. The connector 1 returns automatically to its initial position of FIG. 12A, thanks to the elastic flexible portions 20, 30. Indeed, under normal working conditions, as the flexible portions remain within the elastic deformation range and not in the plastic range, the connector 1 returns to its initial position in which all its components are aligned, i.e. X1=X2.

Advantageously, the ends 42, 52 of the two insulating bodies 4, 5 may be designed such as limiting the tilt angle of the ball joint link. This allows to define a maximum flexion angle of the ball joint link and guarantee that no plastic deformation can appear in the flexible portions 20, 30 of the center contact and outer contact, and that the connector 1 returns to its initial vertical position after unmating.

Other variants and enhancements can be provided without in any way departing from the framework of the invention.

The length and the location of the flexible portions 20, 30 compared to the overall length of the connector 1 depend on the maximum radial misalignment requested and on the nominal distance (height) between the PCB1 and the PCB2 or the filter F. In the shown examples, the length of the flexible portions is of the order of 20% of the overall length of the connector, but other values can be foreseen.

The expression “comprising a” should be understood to be synonymous with “comprising at least one”, unless otherwise specified.

1. A coaxial connector, intended to transmit radio frequency RF signals, comprising:
a central contact comprising two rigid portions each extending along a longitudinal axis and a flexible portion between the two rigid portions and,
an outer contact comprising two rigid portions each extending along a longitudinal axis and a flexible portion between the two rigid portions,
two electrical insulating solid bodies coaxially interposed between the central contact and the outer contact, one of the two bodies being mechanically retained in one of the two rigid portions of the outer contact and mechanically retaining one of the two rigid portions of the central contact, whereas the other of the two bodies is mechanically retained in the other of the two rigid portions of the outer contact and mechanically retains the other of the two rigid portions of the central contact,
wherein the ends of the two insulating bodies which are face-to-face and the flexible portions are configured to allow a ball joint link in flexion around an axis perpendicular to the longitudinal axes.

2. A coaxial connector according to claim 1, wherein the flexible portions of the central and outer contacts are configured to enable an elastic return of the connector to its initial position in which the longitudinal axes are aligned.

3. A coaxial connector according to claim 1, wherein the flexible portion of the central contact and/or the outer contact is (are) in the form of a pleated or corrugated bellows.

4. A coaxial connector according to claim 3, wherein the bellows comprise through slits arranged by creating material discontinuities within the corrugations or pleats of the bellows.

5. A coaxial connector according to claim 1, wherein the surfaces of the two electrical insulating bodies which are face-to-face are complementary shapes.

6. A coaxial connector according to claim 1, wherein the surfaces of the two electrical insulating bodies which are face-to-face are configured to block the ball joint link in a given maximum rotation angle around the axis (Z) perpendicular to the longitudinal axes.

7. A coaxial connector according to claim 1, wherein the two electrical insulating bodies are designed in order to adapt the characteristic impedance of the connector.

8. A coaxial connector according to claim 7, wherein at least one of the two electrical insulating bodies comprises a plurality of holes distributed on its periphery.

9. A coaxial connector according to claim 1, wherein the internal periphery of each of the rigid portions of the outer contact comprises tabs cooperating by snap-fastening with windows formed in the external periphery of each insulating bodies.

10. A coaxial connector according to claim 1, wherein at least one end of the central contact and/or of the outer contact is(are) slotted defining contact petals.

11. A coaxial connector according to claim 1, wherein each of the outer contact and the central contact is a dissymmetric body, the flexible portions being not centred to the middle of said outer and central contacts.

12. A coaxial connector according to claim 1, wherein the central contact and/or the outer contact are each a unique piece made by stamping from a metal sheet.

13. A coaxial connector according to claim 1, wherein at least one end of the outer contact comprising a base, intended to serve as a permanent electrical and mechanical connection with a printed circuit board (PCB1).

14. A coaxial connection assembly to link two printed circuit boards or a PCB and a module (F), comprises:
a coaxial connector according to claim 1, intended to be connected to a first printed circuit board,
a receptacle forming a end socket, called sliding end socket, intended to be connected to a second printed circuit board or integrated in a module,
wherein one end of said first connector is intended to slide in the receptacle.
